(19) United States
(12) Patent Application Publication
(10) Pub. No.: US 2010/0176411 A1
(43) Pub. Date: Jul. 15, 2010

(54) FLUORESCENT-LAMP-TYPE LED LIGHTING DEVICE

(75) Inventor: Fumio Suzuki, Kyoto-shi (JP)

Correspondence Address: ALLEMAN HALL MCCOY RUSSELL & TUTTLE LLP, 806 SW BROADWAY, SUITE 600, PORTLAND, OR, 97205-3335, US

(73) Assignee: ABEL SYSTEMS INCORPORATION, Kyoto-shi, Kyoto (JP)

(21) Appl. No.: 12/667,023

(22) PCT Filed: Jul. 9, 2007
(86) PCT No.: PCT/JP2007/063693

§ 371 Date: Dec. 28, 2009

(30) Foreign Application Priority Data
Jun. 29, 2007 (JP) 2007-171824

(51) Int. Cl. H01L 33/00

(52) U.S. Cl. 257/98; 257/99; 257/E33.059; 257/E33.061

(57) ABSTRACT

To provide a fluorescent-lamp-type LED lighting device that has a large amount of light intensity and that can replace a highly efficient existing lighting device, the fluorescent-lamp-type LED lighting device comprises an LED (3) comprising a thin plate-like semiconductor element body (31) that transmits light generated in a PN junction area (34) in the thickness direction and that emits the light from its surface, a surface electrode (32) arranged to cover the surface of the element body (31) and a plurality of cylindrical dielectric antennas (36) that penetrate the surface electrode (32) in its thickness direction and that condense the light transmitted through the inside of the semiconductor element body (31) and emit the light outside, and a lengthy exterior casing (2) made of resin having translucency. The LED (3) is arranged at both end parts of the exterior casing (2) or along its longitudinal direction. The light emitted from the LED (3) is irradiated outside through the exterior casing (2).

### FIELD OF THE ART

This invention relates to a lengthy fluorescent-lamp-type LED lighting device that uses high efficiency LEDs enabling plane emission.

### BACKGROUND ART

Since an LED has a longer operating life and its light intensity is more stable compared to a fluorescent light or an incandescent lamp, no time is required for starting-up the LED and there is no problem of discarding the LED. Recently a high power LED was developed in addition to the LED that emits blue light or ultraviolet light so applications of LEDs are expanding not only to include conventional indicators but also to include general lighting devices.

However, in view of a total light intensity or an illumination intensity, even though a light intensity per unit illuminating area is increasing, the LED is still behind the fluorescent light. In order to obtain a light intensity comparable to that of the fluorescent light in total, a lot of LEDs are required and a heat release value also gets very big, which requires a heat dissipating member as shown in the patent documents 1 and 2.

One of these causes is that the conventional LED is low in luminous efficiency and small in luminous area. As is known, the LED has an arrangement that a PN junction layer emits light by applying a forward voltage to a semiconductor element having the PN junction layer, and the light generated on the PN junction layer is emitted from the surface of the semiconductor element after the generated light passes the semiconductor element in its thickness direction. However, since an electrode is attached to the surface of the semiconductor element and the electrode blocks the light, it impedes the improvement of the efficiency of transmitting the light outside and impedes increasing the light intensity by enlarging the area. In spite of this, if the area of the electrode is made small, more than a certain level in comparison with the area of the semiconductor element, it becomes impossible to provide a uniform electric field to the entire semiconductor element, thereby declining the luminescent amount. As a result, even though the area of the semiconductor element is enlarged in order to obtain a large amount of the light intensity, there is no other choice but to enlarge the area of the electrode in order to enable the plane emission, which makes it difficult to take a large amount of the light intensity outside because of the light shielding effect. In addition, in view of the problem it is conceived that a transparent electrode such as an ITO is used, however, since a specific resistance of the transparent electrode is bigger in comparison with that of a metal electrode, a loss is generated at the metal electrode so that the luminous efficiency is lowered.

Patent document 1: Japan patent laid-open number 2005-166578
Patent document 2: Japan patent laid-open number 2007-109504
Patent document 3: Japan patent laid-open number 2003-078167

### DISCLOSURE OF THE INVENTION

### Problems to be Solved by the Invention

As mentioned, it is impossible for the conventional LED to increase the luminous efficiency in a given electric power to a value more than a certain value. In addition, it is also difficult to emit the light in a large area by means of a single element, namely, it is difficult to emit the light having a large amount of the light intensity by means of a single element.

Then, as shown in the patent document 3, an inventor of this invention has focused attention on the light being an electromagnetic wave and has developed an innovative LED wherein the multiple microscopic dielectric antennas that condense and transmit the light by means of the antenna effect to the light are arranged to penetrate an electrode. With this LED, it is possible to take the light outside with high efficiency by enabling an ideal plane emission.

The present claimed invention intends to provide an LED lighting device that can substitute for an existing lighting device such as a fluorescent lamp by making use of the LED that can take the light outside with high efficiency by enabling the ideal plane emission with a single element.

### Means to Solve the Problems

More specifically, the fluorescent lamp type LED lighting device in accordance with this invention comprises an LED comprising a thin plate-like semiconductor element body that transmits light generated in a PN junction area in the thickness direction and that emits the light from its surface, a surface electrode arranged to cover the surface of the semiconductor element body and a plurality of cylindrical dielectric antennas that penetrate the surface electrode in its thickness direction and that condense the light transmitted through the inside of the semiconductor element body and that emit the light outside, and a lengthy exterior casing made of resin having translucency. And the LED is arranged at both end parts of the exterior casing or along a longitudinal direction of the exterior casing and the light emitted from the LED is irradiated outside through the exterior casing.

With this arrangement, since a uniform electric field can be given to the semiconductor element body of the LED because of the surface electrode, a large amount of the light intensity can be obtained with ease by enabling the ideal plane emission in a large area. Meanwhile, since a plurality of dielectric antennas are arranged to penetrate the surface electrode, the light being an electromagnetic wave is condensed by the dielectric antennas and emitted outside, thereby enabling a large reduction of a shading effect by means of the surface electrode. More specifically, it is possible to generate a large amount of the light intensity due to the ideal plane emission in a large area and to bring the generated light to outside with high efficiency.

Furthermore, with this invention, since it is possible not only to secure a light intensity necessary for a general lighting device but also to reduce generation of heat because of its high efficiency, the exterior casing made of resin can be used without requiring any heat dissipating member. With this arrangement where an exterior casing made of resin can be used, selectivity of a shape or a material of the exterior casing can be enlarged and the exterior casing can produce various lens functions or light diffusing functions, thereby enabling preferable lighting for various purposes.

As a concrete embodiment represented herein the LED irradiates white light and the exterior casing is transparent.

In order to give variations to a luminescent color, it is preferable that a fluorescent material is applied to a surface of the exterior casing or mixed into an inside of the exterior casing and the light emitted from the LED is irradiated outside while making the fluorescent material produce fluorescence.

### EFFECT OF THE INVENTION

In accordance with this invention having the above-mentioned arrangement, since the LED lighting device enables nonconventional plane emission with a large amount of the light intensity and a high efficiency and selectivity of a shape or a material of the exterior casing is enlarged and the arrangement of the LED lighting device requires no heat dissipating member, it is possible to conduct not only general lighting but also a preferable lighting for various purposes.

### BRIEF DESCRIPTION OF THE DRAWINGS

FIG. 1 is a general view showing an internal structure of a fluorescent lamp type LED lighting device in accordance with one embodiment of this invention.

FIG. 2 is a pattern cross-sectional view showing an internal structure of an exterior casing in accordance with this embodiment.

FIG. 3 is a pattern cross-sectional view of a plane emission LED in accordance with this embodiment.

FIG. 4 is a pattern perspective view of the plane emission LED in accordance with this embodiment.

FIG. 5 is a pattern cross-sectional view of a plane emission LED in accordance with another embodiment of this invention.

FIG. 6 is a perspective view showing a fluorescent lamp type LED lighting device in accordance with a further different embodiment of this invention.

FIG. 7 is a pattern cross-sectional view showing an internal structure of the fluorescent lamp type LED lighting device in accordance with this embodiment.

FIG. 8 is a pattern perspective view showing a structure of a diffraction sheet in accordance with this embodiment.

FIG. 9 is a pattern cross-sectional view of a fluorescent lamp type LED lighting device in accordance with a further different embodiment of this invention.

### BEST MODES OF EMBODYING THE INVENTION

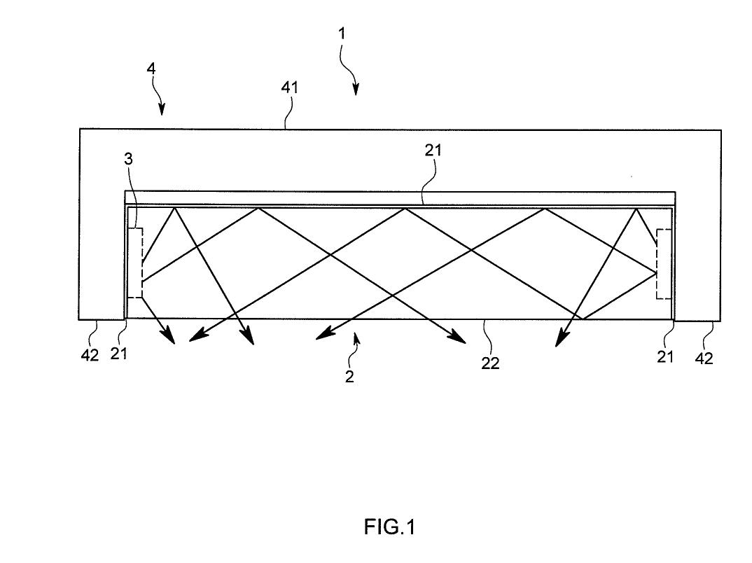

Embodiments of this invention will be explained with reference to FIG. 1 through FIG. 9.

An LED lighting device 1 in accordance with this embodiment is used for general lighting such as a room lighting instead of, for example, a fluorescent lamp, and comprises, as shown in FIG. 1, an exterior casing 2, an LED 3 mounted on the exterior casing 2 and a holding member 4 that holds the exterior casing 2 and the LED 3.

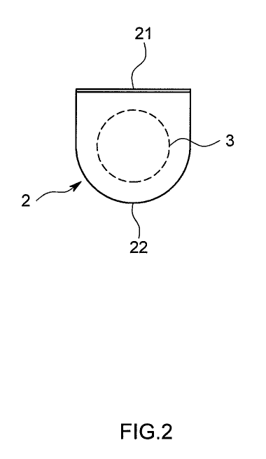

The exterior casing 2 is transparent and made of resin in a columnar shape whose cross-section is generally a half circle as shown in FIG. 2. In this embodiment, an inward-looking reflecting plate 21 is mounted on both end surfaces and a plane part of a side circumferential surface, respectively, so that the light introduced from the LED 3, to be described later, into inside of the exterior casing 2 exits from a cylindrical outer surface part 22 as being a side circumferential surface on which the reflecting plate 21 is not mounted.

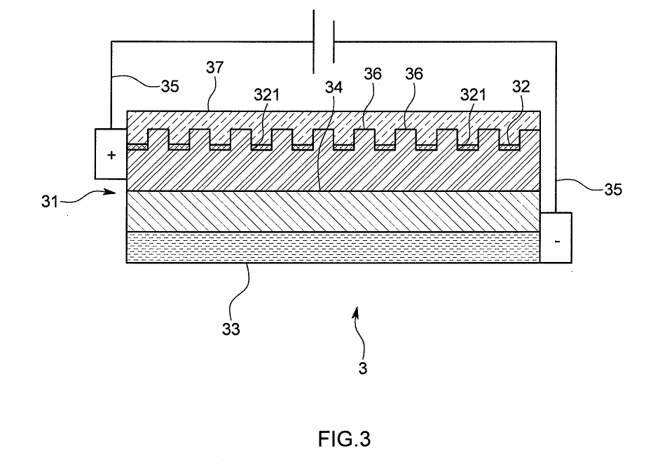

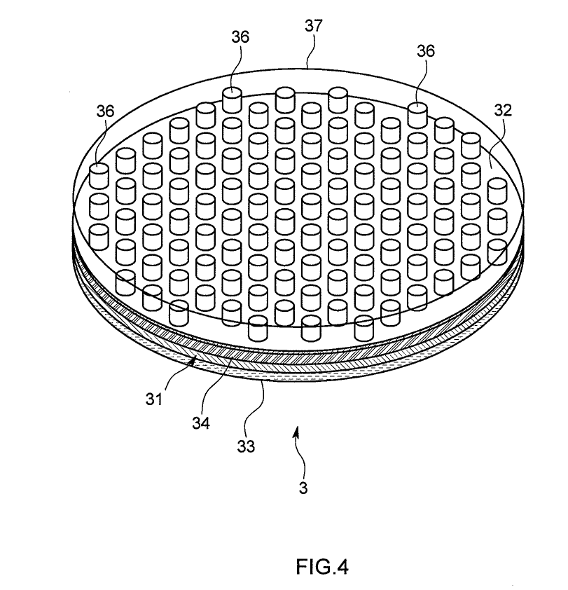

The LED 3 is, as shown in FIG. 3, in a rectangular plate shape or a circle plate shape and of a plane emission type that irradiates white light from a surface of one of the face plate parts of the rectangular plate shape or the circle plate shape, and mounted on each end part of the exterior casing 2 with its luminous surfaces facing each other. More specifically, the LED 3 comprises, as shown in FIG. 3 and FIG. 4, a semiconductor element body 31 in a thin plate shape having a PN junction structure, a surface electrode 32 arranged to generally cover a front surface of the semiconductor element body 31, and a reflecting plate also serving as a back surface electrode 33 arranged to generally cover a back surface of the semiconductor element body 31. The LED 3 emits the light from a PN junction area 34 formed in the middle of the LED 3 toward a direction of the thickness. A lead wire 35 for supplying electric power is connected to a peripheral part of the semiconductor element body 31.

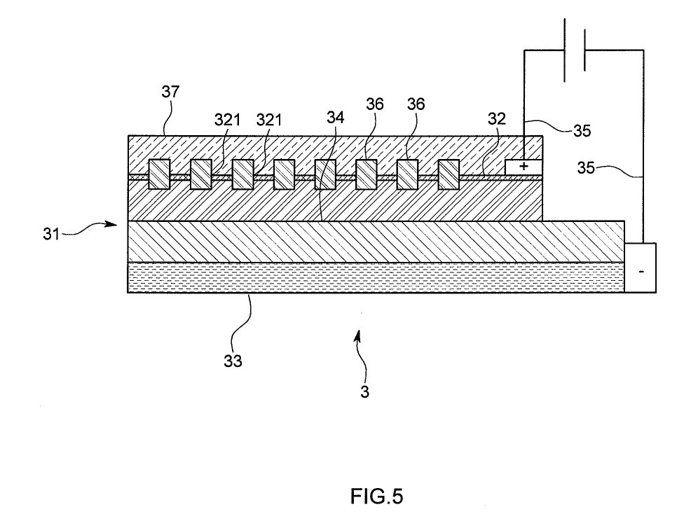

As shown in FIG. 3 and FIG. 4, a plurality of through bores 321 are formed in the thickness direction at a certain pitch on the surface electrode 32. At each through bore 321 arranged is a dielectric antenna 36 having a size so as to collect and transmit the light emitted from the semiconductor body 31. In order to effectively produce the function as the dielectric antenna 36 for the light, it is necessary for the dielectric antenna 36 to be of a size that both a height and a width (a diameter) are about from a fraction of the wavelength of the light to dozens of the wavelength of the light. More preferably, the size of the dielectric antenna 36 is about from one third to triple of the wavelength of the light. In addition, a shape of the dielectric antenna 36 is a cylinder in FIG. 3 and FIG. 4, however, it may be a polygonal column or an elliptic cylinder. Furthermore, the dielectric antenna 36 may be integrally formed with the semiconductor element body 31 or may be made of a member whose dielectric constant is different, as shown in FIG. 5.

Furthermore, in this embodiment, as shown in FIG. 3, a fluorescent resin layer 37 such as YAG phosphor is arranged further outside of the surface electrode 32. With this arrangement, the light from the semiconductor element body 31 and the fluorescence from the fluorescent resin layer 37 are mixed so that several colors are mixed and then the white light is irradiated outside as mentioned.

The holding member 4 comprises, as shown in FIG. 1, a hollow lengthy body 41 and a pair of arms 42 elongating at a right angle from each end part of the body 41. The exterior casing 2 and the LED 3 are detachably supported by the holding member 4 by connecting a connector, not shown in drawings, arranged on each arm 42 with a connector, not shown in drawings, arranged at an end part of the exterior casing 2. The connector on the arm 42 is connected to a rectifying circuit, not shown in drawings, incorporated in the body 41 and the connector of the exterior body 2 is connected to the LED 3 so that the LED 3 is supplied with electric power and emits light by mounting the exterior casing 2 and the LED 3 on the holding member 4.

Next, an operation of the LED lighting device 1 having the above-mentioned arrangement will be briefly explained.

If the LED 3 emits light at a time when the electric power is supplied, a part of the light emitted from each LED 3 is irradiated outside from the cylindrical outer surface part 22 and the rest of the light reflects on the cylindrical outer surface part 22 or the reflecting plate 21 internally and eventually the light is irradiated outside from the cylindrical outer surface part 22. As mentioned, after several times of reflections inside the exterior casing 2, the cylindrical outer surface part 22 emits light uniformly.

In accordance with the LED lighting device 1 having the above-mentioned arrangement, since a uniform electric field can be provided to the semiconductor element body 31 of the LED 3 by the surface electrode 32, it is possible to easily obtain a large amount of the light intensity by enabling ideal plane emission of the semiconductor element body 31. Meanwhile, since a plurality of dielectric antennas 36 are arranged to penetrate the surface electrode 32, the light being an electromagnetic wave is condensed and emitted outside, thereby enabling a large reduction of a shading effect by the surface electrode 32. More specifically, since the LED 3 comprises the surface electrode 32 and the dielectric antenna 36, it is possible to produce a large amount of light intensity and to bring the generated light to outside with high efficiency.

As a result, since it is possible not only to secure a light intensity necessary for a general lighting device but also to reduce generation of heat because of high efficiency, any heat dissipating member is not required.

Furthermore, the resin can be used for the exterior casing 2 because the heat generation is restrained, which makes it possible to enlarge selectivity of a shape or a material of the exterior casing 2. As a result, the exterior casing 2 can produce various lens functions or light diffusing functions so as to enable preferable lighting for various purposes.

In addition, since the cylindrical outer surface part 22 emits the light uniformly by reflecting the light irradiated from the LED 3 inside of the exterior casing 2 several times, it is possible to equalize the brightness of the illuminating surface.

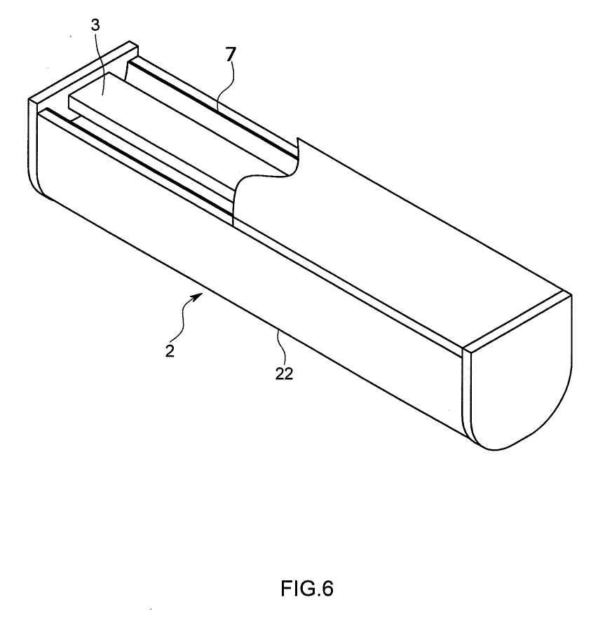

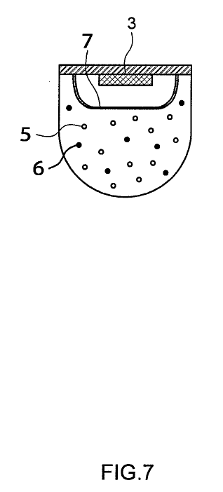

The present claimed invention is not limited to the above-mentioned embodiment. The same parts as those in the first embodiment are denoted by the same reference numerals as those in the embodiment, and descriptions thereof will be omitted. For example, the LED lighting device 1 shown in FIG. 6 and FIG. 7 has an arrangement wherein the LED 3 of a straight band shape is attached to a side peripheral surface of the exterior casing 2 so as to make the illuminating surface parallel to a longitudinal direction of the exterior casing 2. The exterior casing 2 comprises a groove that extends in a longitudinal direction of the exterior casing 2 at a body side of the holding member, not shown in drawings, and a diffraction sheet 7 that disperses the light is arranged on a bottom surface of the groove. In addition, a particulate fluorescent material 5 and a particulate light scattering particle 6 are mixed inside of the exterior casing 2.

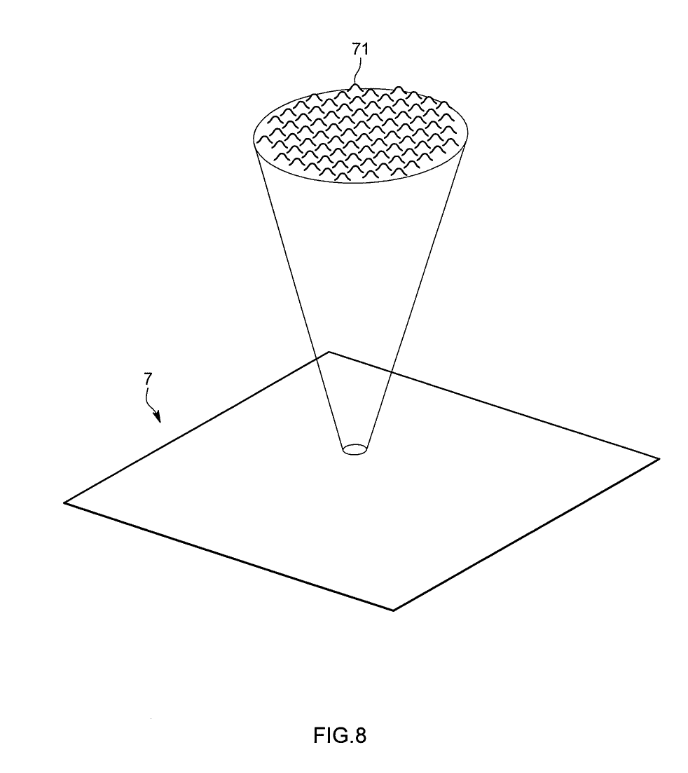

The diffraction sheet 7 is, as shown in FIG. 8, provided with micro-projections 71 regularly arranged on a film that transmits and inflects the light. It is preferable that an interval between each micro-projection 71 is from 30 nm to 100 μm. In addition, an interval between each micro-projection 71 may differ for every group such that an interval between micro-projections 71 for a certain line is 30 nm and an interval between micro-projections 71 for another line is 100 nm.

An operation of the LED lighting device 1 having this arrangement will be explained briefly. When the LED lighting device 1 is powered on, ultraviolet light or blue light is irradiated from the LED 3 toward the groove of the exterior casing 2 and dispersed into multiple point light sources or a line light source without any loss of the light intensity by means of the transparent diffraction sheet 7. A part of the dispersed light produces fluorescence on the fluorescent material 5 and then goes outside from the exterior casing 2 while being scattered by the light scattering particle 6. Other light goes out from the exterior casing 2 without producing fluorescence on the fluorescent material 5 and then is mixed with the fluorescent light.

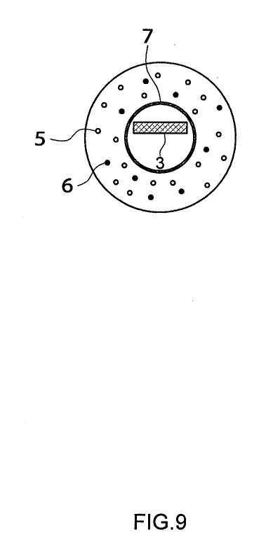

In addition, as shown in FIG. 9, the LED 3 may be arranged at a through bore formed at a center of the exterior casing 2.

Furthermore, the fluorescent material may be applied to a surface of the exterior casing. As a means for scattering the light, a surface of the exterior casing may be provided with a surface processing by means of sandblasting instead of the light scattering particle. In addition, the LED is not limited to a single LED and may be a line comprising multiple LEDs arranged in a line. The LED may be an LED without using a dielectric antenna.

The present claimed invention is not limited to the above-mentioned illustrated examples or embodiments and may be variously modified without departing from the spirit of the invention.

### POSSIBLE APPLICATIONS IN INDUSTRY

In accordance with this invention having the above-mentioned arrangement, since the LED lighting device enables nonconventional plane emission with a large amount of the light intensity and a high efficiency and selectivity of a shape or a material of the exterior casing is enlarged and the arrangement of the LED lighting device requires no heat dissipating member, it is possible to conduct not only general lighting but also a preferable lighting for various purposes.

1. An LED lighting device comprising an LED comprising a thin plate-like semiconductor element body that transmits light generated in a PN junction area in a thickness direction and that emits the light from its surface, a surface electrode arranged to cover the surface of the semiconductor element body and a plurality of cylindrical dielectric antennas that penetrate the surface electrode in its thickness direction and that condense the light transmitting through an inside of the semiconductor element body and that emit the light outside, and a lengthy exterior casing made of resin having translucency, wherein the LED is arranged at both end parts of the exterior casing or along a longitudinal direction of the exterior casing and the light emitted from the LED is irradiated outside through the exterior casing.

2. The LED lighting device described in claim 1, wherein the LED irradiates white light and the exterior casing is transparent.

3. The LED lighting device described in claim 1, wherein a fluorescent material is applied to a surface of the exterior casing or mixed into an inside of the exterior casing and the light emitted from the LED is irradiated outside while making the fluorescent material produce fluorescence.
